(19) United States
(12) Patent Application Publication
(10) Pub. No.: US 2026/0032867 A1
(43) Pub. Date: Jan. 29, 2026

(54) DUST COVER FOR ELECTRONIC COMPONENTS

(71) Applicant: Aristocrat Technologies Australia Pty Limited, North Ryde (AU)

(72) Inventors: Mariette Girgis, The Ponds (AU); Saar Caspi, Botany (AU); Zhiqiang Liang, Telopea (AU); Samantha Kraft, Summerland Point (AU); Ivan Ooi, Macquarie Park (AU)

(21) Appl. No.: 18/807,353

(22) Filed: Aug. 16, 2024

Related U.S. Application Data
(60) Provisional application No. 63/676,196, filed on Jul. 26, 2024.

(51) Int. Cl. H05K 7/20; G07F 17/32

(52) U.S. Cl. CPC H05K 7/2039; G07F 17/3216

(57) ABSTRACT

A dust cover for an electronics assembly is provided. The dust cover may have a planar body portion having a planar top surface, a plurality of side walls extending from the planar body portion in a direction substantially perpendicular to the planar top surface and at least partially defining a plurality of compartments, a first removable cover connected to the planar body portion, positioned over a first compartment, and configured to be removable without a tool, and a curved airflow surface connected to the planar body portion. Each side wall has a proximate end connected to the planar body portion and a distal end offset from the planar body portion, the distal ends form a reference plane offset from the planar body portion, and at least a portion of the curved airflow surface is interposed between the reference plane and the planar body portion.

### RELATED APPLICATION

The present application claims priority to U.S. Provisional Patent Application No. 63/676,196, filed Jul. 26, 2024, and entitled “DUST COVER FOR ELECTRONIC COMPONENTS” (Attorney Docket No. ARISP086PUS) which is hereby incorporated by reference in its entirety.

### BACKGROUND

Electronic gaming machines (“EGMs”) or gaming devices provide a variety of wagering games such as slot games, video poker games, video blackjack games, roulette games, video bingo games, keno games and other types of games that are frequently offered at casinos and other locations. Play on EGMs typically involves a player establishing a credit balance by inputting money, or another form of monetary credit, and placing a monetary wager (from the credit balance) on one or more outcomes of an instance (or single play) of a primary or base game. In some cases, a player may qualify for a special mode of the base game, a secondary game, or a bonus round of the base game by attaining a certain winning combination or triggering event in, or related to, the base game, or after the player is randomly awarded the special mode, secondary game, or bonus round. In the special mode, secondary game, or bonus round, the player is given an opportunity to win extra game credits, game tokens or other forms of payout. In the case of “game credits” that are awarded during play, the game credits are typically added to a credit meter total on the EGM and can be provided to the player upon completion of a gaming session or when the player wants to “cash out.”

“Slot” type games are often displayed to the player in the form of various symbols arrayed in a row-by-column grid or matrix. Specific matching combinations of symbols along predetermined paths (or paylines) through the matrix indicate the outcome of the game. The display typically highlights winning combinations/outcomes for identification by the player. Matching combinations and their corresponding awards are usually shown in a “pay-table” which is available to the player for reference. Often, the player may vary his/her wager to include differing numbers of paylines and/or the amount bet on each line. By varying the wager, the player may sometimes alter the frequency or number of winning combinations, frequency or number of secondary games, and/or the amount awarded.

Typical games use a random number generator (RNG) to randomly determine the outcome of each game. The game is designed to return a certain percentage of the amount wagered back to the player over the course of many plays or instances of the game, which is generally referred to as return to player (RTP). The RTP and randomness of the RNG ensure the fairness of the games and are highly regulated. Upon initiation of play, the RNG randomly determines a game outcome and symbols are then selected which correspond to that outcome. Notably, some games may include an element of skill on the part of the player and are therefore not entirely random.

Electronic gaming machines are complex devices with display devices and are often housed within cabinets having multiple access points in the form of doors or trays that may be opened or slid out in order to access internal components, cables, connectors, etc.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some embodiments, a dust cover for an electronics assembly is provided. The dust cover may have a planar body portion having a planar top surface, a plurality of side walls extending from the planar body portion in a direction substantially perpendicular to the planar top surface and at least partially defining a plurality of compartments, a first removable cover connected to the planar body portion, positioned over a first compartment, and configured to be removable without a tool, and a curved airflow surface connected to the planar body portion and having a nonlinear cross-sectional profile. Each side wall may have a proximate end connected to the planar body portion and a distal end offset from the planar body portion, the distal ends of the plurality of side walls may form a reference plane that is offset from the planar body portion, and at least a portion of the curved airflow surface may be interposed between the reference plane and the planar body portion.

In some embodiments, the planar body portion may define an opening configured to receive a heat sink.

In some such embodiments, the planar body portion may extend around all of the opening when viewed perpendicular to the planar top surface.

In some embodiments, the curved airflow surface may have a surface proximal end connected to the planar body portion and a surface distal end interposed between the reference plane and the planar body portion when viewed from an angle parallel to the planar top surface.

In some embodiments, the curved airflow surface may extend for a width in a direction parallel to the planar top surface, and the curved airflow surface may have a nonlinear cross-sectional profile in a direction perpendicular to the width that is curved.

In some such embodiments, the nonlinear cross-sectional profile may be S-shaped.

In some embodiments, the dust cover may further have a peninsula extending from the planar body portion, and the peninsula may have a first surface co-planar with the planar top surface of the planar body portion.

In some embodiments, the dust cover may further have a second removable cover connected to the planar body portion, positioned over a second compartment, and configured to be removable without a tool.

In some such embodiments, the first removable cover and the second removable cover may be different sizes.

In some embodiments, a first subset of side walls may extend around all of the first compartment, and a second subset of side walls may extend around at least some of a second compartment.

In some embodiments, two side walls may partially define the first compartment and a third compartment.

In some embodiments, the first removable cover may be configured to connect with the planar body portion with a snap joint.

In some embodiments, an electronics assembly may be provided. The electronic assembly may have a mounting tray, a printed circuit board (PCB) directly or indirectly connected to the mounting tray, a heat sink connected to the PCB and extending away from the PCB and the mounting tray in a first direction, and a dust cover directly or indirectly connected to the mounting tray and having a planar body portion having a planar top surface and an opening extending through and defined by the planar body portion, and a curved airflow surface connected to the planar body portion and having a nonlinear cross-sectional profile. The heat sink may extend through the opening, the PCB may be interposed between the mounting tray and the planar body portion of the dust cover, and at least a portion of the curved airflow surface may be interposed between the PCB and the planar body portion.

In some embodiments, the curved airflow surface may be adjacent to the opening and the heat sink.

In some embodiments, the dust cover may further have a plurality of side walls extending from the planar body portion in a direction substantially perpendicular to the planar top surface and defining a plurality of compartments, and a first removable cover connected to the planar body portion, positioned over a first compartment, and configured to be removable without a tool.

In some such embodiments, the electronics assembly may further have one or more batteries. The one or more batteries may be positioned inside the first compartment, and the first removable cover may be positioned over the one or more batteries.

In some such embodiments, the electronics assembly may further have one or more memory cards. The one or more memory cards may be positioned inside the first compartment, and the first removable cover may be positioned over the one or more memory cards.

In some further such embodiments, a first subset of side walls may extend around all of the first compartment.

In some embodiments, the electronics assembly may further have a second heat sink extending away from the mounting tray in the first direction, and the curved airflow surface may be interposed between the opening and the second heat sink when viewed perpendicular to the planar top surface.

In some such embodiments, the dust cover may further have a peninsula extending from the planar body portion. The peninsula may have a first surface co-planar with the planar top surface, the peninsula may be adjacent to the curved airflow surface, the curved airflow surface may extend around a first side of the second heat sink, and the peninsula may extend around a second side of the second heat sink.

Additional aspects will be set forth in the detailed description which follows, and, in part, will be apparent from the disclosure, or may be learned by practice of the disclosed embodiments and/or the claimed subject matter.

The foregoing general description and the following detailed description are illustrative and explanatory and are intended to provide further explanation of the claimed subject matter.

### BRIEF DESCRIPTION OF THE DRAWINGS

FIG. 1 is an exemplary diagram showing several EGMs networked with various gaming-related servers.

FIG. 2A is a block diagram showing various functional elements of an exemplary EGM.

FIG. 2B depicts a casino gaming environment according to one example.

FIG. 2C is a diagram that shows examples of components of a system for providing online gaming according to some aspects of the present disclosure.

FIG. 3 illustrates, in block diagram form, an implementation of a game processing architecture algorithm that implements a game processing pipeline for the play of a game in accordance with various implementations described herein.

FIG. 4 depicts an off-angle view of a dust cover, in accordance with disclosed embodiments.

FIG. 5 depicts an exploded view of the dust cover of FIG. 4.

FIG. 6 depicts a front view of the dust cover of FIG. 4.

FIG. 7 depicts a magnified detail view of a portion of FIG. 6.

FIG. 8A depicts a different off-angle view of the dust cover of FIG. 4.

FIG. 8B depicts the dust cover of FIG. 8A, in accordance with various embodiments

FIG. 8C depicts a bottom view of the dust cover of FIG. 8A, in accordance to disclosed embodiments.

FIG. 8D depicts yet another off-angle view of the dust cover of FIG. 4.

FIG. 9 depicts an off-angle view of an electronics assembly, in accordance with disclosed embodiments.

FIG. 10 depicts an off-angle exploded view of the electronics assembly of FIG. 9, in accordance with disclosed embodiments.

The Figures are provided for the purpose of providing examples and clarity regarding various aspects of this disclosure and are not intended to be limiting.

### DETAILED DESCRIPTION

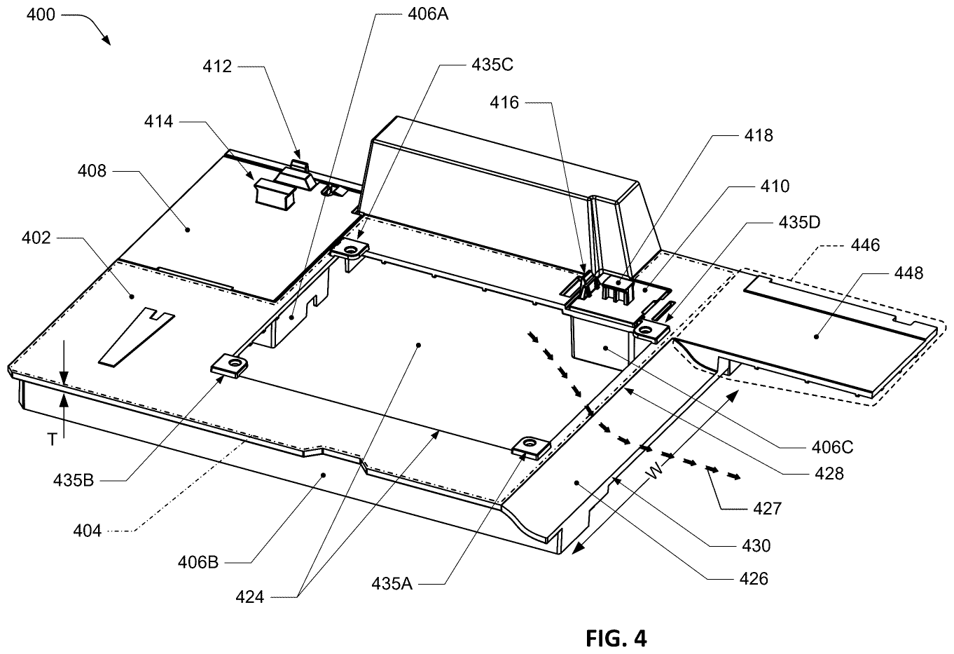

The following discussion provides overall context for electronic gaming machines, some of which may include an enclosure such as those discussed later herein starting with FIG. 4.

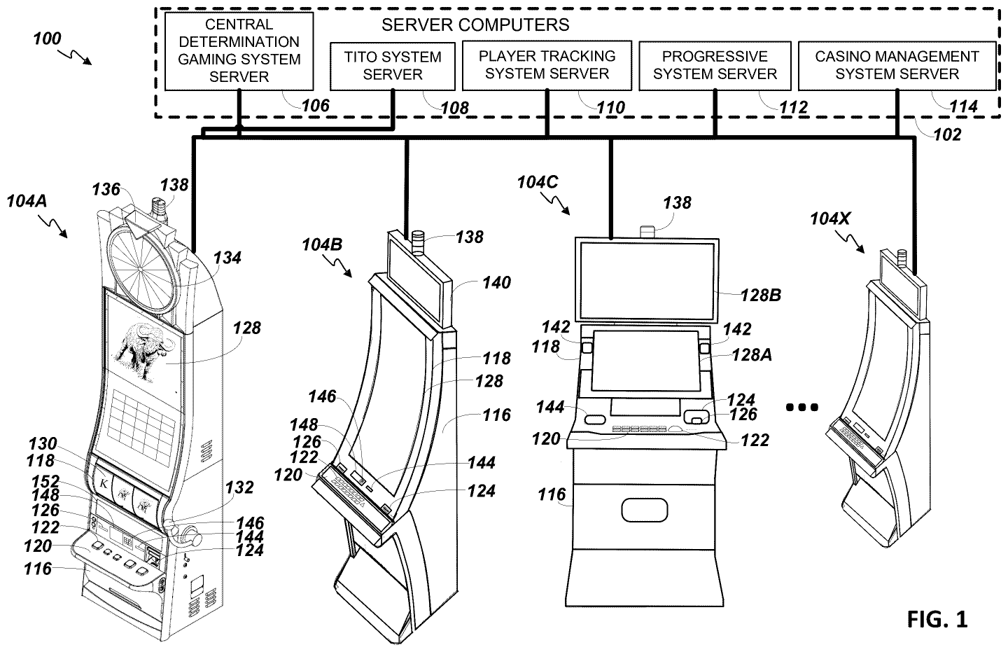

FIG. 1 illustrates several different models of EGMs which may be networked to various gaming-related servers. Shown is a system 100 in a gaming environment including one or more server computers 102 (e.g., slot servers of a casino) that are in communication, via a communications network, with one or more gaming devices 104A-104X (EGMs, slots, video poker, bingo machines, etc.) that can implement one or more aspects of the present disclosure. The gaming devices 104A-104X may alternatively be portable and/or remote gaming devices such as, but not limited to, a smart phone, a tablet, a laptop, or a game console. Gaming devices 104A-104X utilize specialized software and/or hardware to form non-generic, particular machines or apparatuses that comply with regulatory requirements regarding devices used for wagering or games of chance that provide monetary awards.

Communication between the gaming devices 104A-104X and the server computers 102, and among the gaming devices 104A-104X, may be direct or indirect using one or more communication protocols. As an example, gaming devices 104A-104X and the server computers 102 can communicate over one or more communication networks, such as over the Internet through a website maintained by a computer on a remote server or over an online data network including commercial online service providers, Internet service providers, private networks (e.g., local area networks and enterprise networks), and the like (e.g., wide area networks). The communication networks could allow gaming devices 104A-104X to communicate with one another and/or the server computers 102 using a variety of communication-based technologies, such as radio frequency (RF) (e.g., wireless fidelity (WiFi®) and Bluetooth®), cable TV, satellite links and the like.

In some implementations, server computers 102 may not be necessary and/or preferred. For example, in one or more implementations, a stand-alone gaming device such as gaming device 104A, gaming device 104B or any of the other gaming devices 104C-104X can implement one or more aspects of the present disclosure. However, it is typical to find multiple EGMs connected to networks implemented with one or more of the different server computers 102 described herein.

The server computers 102 may include a central determination gaming system server 106, a ticket-in-ticket-out (TITO) system server 108, a player tracking system server 110, a progressive system server 112, and/or a casino management system server 114. Gaming devices 104A-104X may include features to enable operation of any or all servers for use by the player and/or operator (e.g., the casino, resort, gaming establishment, tavern, pub, etc.). For example, game outcomes may be generated on a central determination gaming system server 106 and then transmitted over the network to any of a group of remote terminals or remote gaming devices 104A-104X that utilize the game outcomes and display the results to the players.

Gaming device 104A is often of a cabinet construction which may be aligned in rows or banks of similar devices for placement and operation on a casino floor. The gaming device 104A often includes a main door which provides access to the interior of the cabinet. Gaming device 104A typically includes a button area or button deck 120 accessible by a player that is configured with input switches or buttons 122, an access channel for a bill validator 124, and/or an access channel for a ticket-out printer 126.

In FIG. 1, gaming device 104A is shown as a Relm XL™ model gaming device manufactured by Aristocrat® Technologies, Inc. As shown, gaming device 104A is a reel machine having a gaming display area 118 comprising a number (typically 3 or 5) of mechanical reels 130 with various symbols displayed on them. The mechanical reels 130 are independently spun and stopped to show a set of symbols within the gaming display area 118 which may be used to determine an outcome to the game.

In many configurations, the gaming device 104A may have a main display 128 (e.g., video display monitor) mounted to, or above, the gaming display area 118. The main display 128 can be a high-resolution liquid crystal display (LCD), plasma, light emitting diode (LED), or organic light emitting diode (OLED) panel which may be flat or curved as shown, a cathode ray tube, or other conventional electronically controlled video monitor.

In some implementations, the bill validator 124 may also function as a “ticket-in” reader that allows the player to use a casino issued credit ticket to load credits onto the gaming device 104A (e.g., in a cashless ticket (“TITO”) system). In such cashless implementations, the gaming device 104A may also include a “ticket-out” printer 126 for outputting a credit ticket when a “cash out” button is pressed. Cashless TITO systems are used to generate and track unique bar-codes or other indicators printed on tickets to allow players to avoid the use of bills and coins by loading credits using a ticket reader and cashing out credits using a ticket-out printer 126 on the gaming device 104A. The gaming device 104A can have hardware meters for purposes including ensuring regulatory compliance and monitoring the player credit balance. In addition, there can be additional meters that record the total amount of money wagered on the gaming device, total amount of money deposited, total amount of money withdrawn, total amount of winnings on gaming device 104A.

In some implementations, a player tracking card reader 144, a transceiver for wireless communication with a mobile device (e.g., a player's smartphone), a keypad 146, and/or an illuminated display 148 for reading, receiving, entering, and/or displaying player tracking information is provided in gaming device 104A. In such implementations, a game controller within the gaming device 104A can communicate with the player tracking system server 110 to send and receive player tracking information.

Gaming device 104A may also include a bonus topper wheel 134. When bonus play is triggered (e.g., by a player achieving a particular outcome or set of outcomes in the primary game), bonus topper wheel 134 is operative to spin and stop with indicator arrow 136 indicating the outcome of the bonus game. Bonus topper wheel 134 is typically used to play a bonus game, but it could also be incorporated into play of the base or primary game.

A candle 138 may be mounted on the top of gaming device 104A and may be activated by a player (e.g., using a switch or one of buttons 122) to indicate to operations staff that gaming device 104A has experienced a malfunction or the player requires service. The candle 138 is also often used to indicate a jackpot has been won and to alert staff that a hand payout of an award may be needed.

There may also be one or more information panels 152 which may be a back-lit, silkscreened glass panel with lettering to indicate general game information including, for example, a game denomination (e.g., $0.25 or $1), pay lines, pay tables, and/or various game related graphics. In some implementations, the information panel(s) 152 may be implemented as an additional video display.

Gaming devices 104A have traditionally also included a handle 132 typically mounted to the side of main cabinet 116 which may be used to initiate game play.

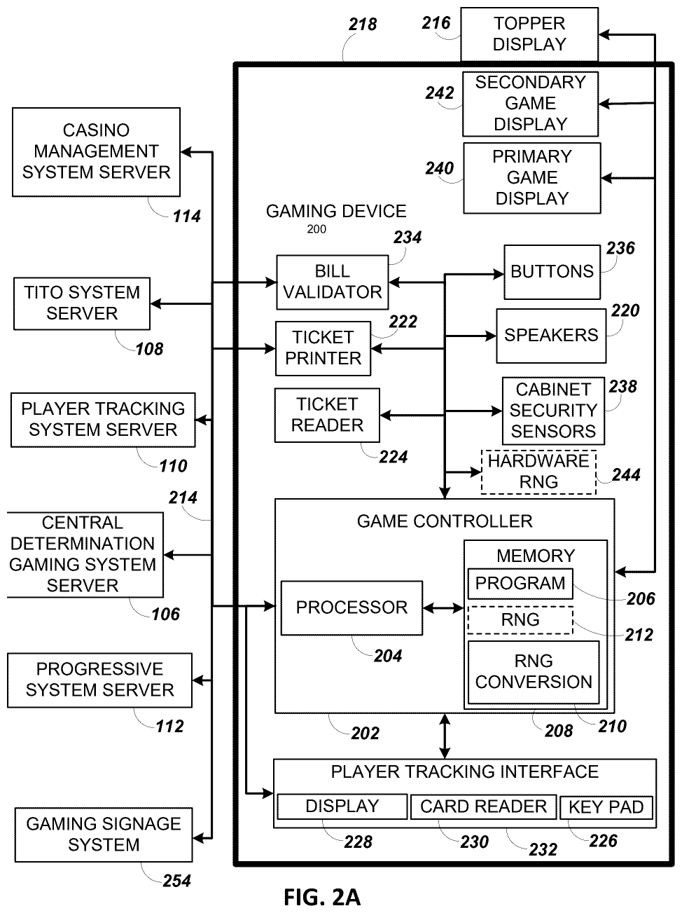

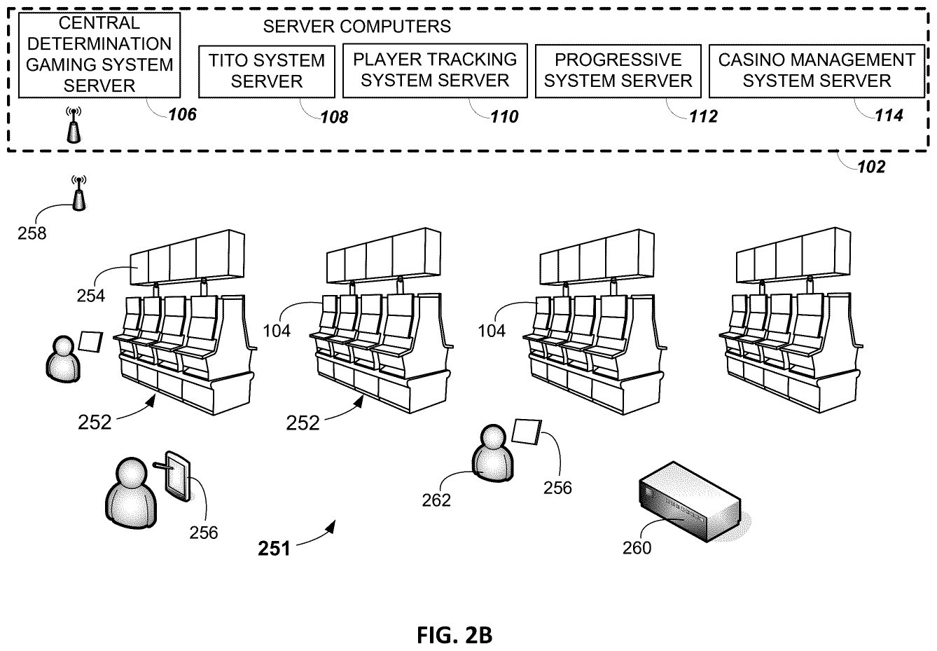

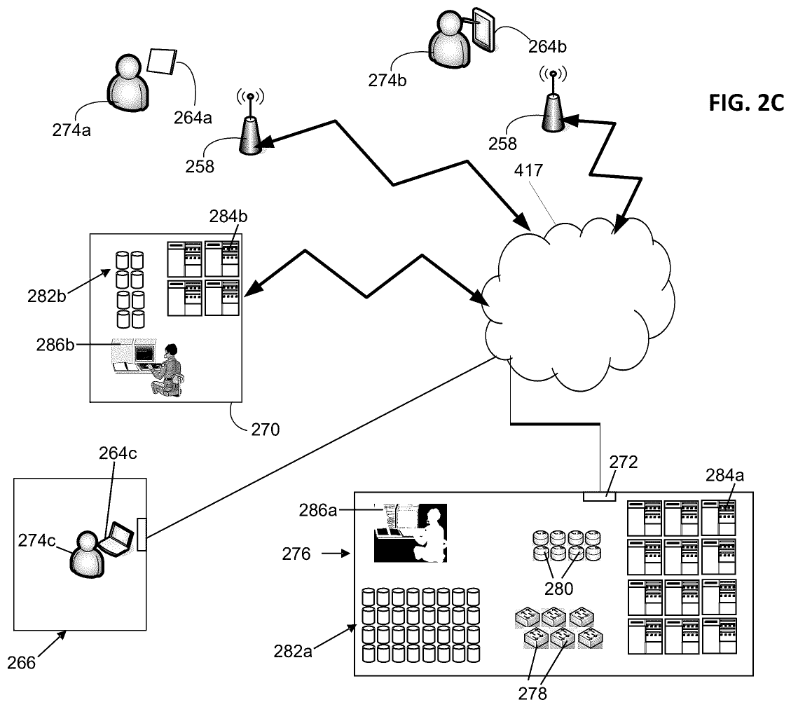

Many or all the above-described components can be controlled by circuitry (e.g., a game controller) housed inside the main cabinet 116 of the gaming device 104A, the details of which are shown in FIG. 2A.

An alternative example gaming device 104B illustrated in FIG. 1 is the Arc™ model gaming device manufactured by Aristocrat® Technologies, Inc. Note that where possible, reference numerals identifying similar features of the gaming device 104A implementation are also identified in the gaming device 104B implementation using the same reference numbers. Gaming device 104B does not include physical reels and instead shows game play functions on main display 128. An optional topper screen 140 may be used as a secondary game display for bonus play, to show game features or attraction activities while a game is not in play, or any other information or media desired by the game designer or operator. In some implementations, the optional topper screen 140 may also or alternatively be used to display progressive jackpot prizes available to a player during play of gaming device 104B.

Example gaming device 104B includes a main cabinet 116 including a main door which opens to provide access to the interior of the gaming device 104B. The main or service door is typically used by service personnel to refill the ticket-out printer 126 and collect bills and tickets inserted into the bill validator 124. The main or service door may also be accessed to reset the machine, verify and/or upgrade the software, and for general maintenance operations.

Another example gaming device 104C shown is the Helix™ model gaming device manufactured by Aristocrat® Technologies, Inc. Gaming device 104C includes a main display 128A that is in a landscape orientation. Although not illustrated by the front view provided, the main display 128A may have a curvature radius from top to bottom, or alternatively from side to side. In some implementations, main display 128A is a flat panel display. Main display 128A is typically used for primary game play while secondary display 128B is typically used for bonus game play, to show game features or attraction activities while the game is not in play or any other information or media desired by the game designer or operator. In some implementations, example gaming device 104C may also include speakers 142 to output various audio such as game sound, background music, etc.

Many different types of games, including mechanical slot games, video slot games, video poker, video blackjack, video pachinko, keno, bingo, and lottery, may be provided with or implemented within the depicted gaming devices 104A-104C and other similar gaming devices. Each gaming device may also be operable to provide many different games. Games may be differentiated according to themes, sounds, graphics, type of game (e.g., slot game vs. card game vs. game with aspects of skill), denomination, number of paylines, maximum jackpot, progressive or non-progressive, bonus games, and may be deployed for operation in Class 2 or Class 3, etc.

FIG. 2A is a block diagram depicting exemplary internal electronic components of a gaming device 200 connected to various external systems. All or parts of the gaming device 200 shown could be used to implement any one of the example gaming devices 104A-X depicted in FIG. 1. As shown in FIG. 2A, gaming device 200 includes a topper display 216 or another form of a top box (e.g., a topper wheel, a topper screen, etc.) that sits above cabinet 218. Cabinet 218 or topper display 216 may also house a number of other components which may be used to add features to a game being played on gaming device 200, including speakers 220, a ticket printer 222 which prints bar-coded tickets or other media or mechanisms for storing or indicating a player's credit value, a ticket reader 224 which reads bar-coded tickets or other media or mechanisms for storing or indicating a player's credit value, and a player tracking interface 232. Player tracking interface 232 may include a keypad 226 for entering information, a player tracking display 228 for displaying information (e.g., an illuminated or video display), a card reader 230 for receiving data and/or communicating information to and from media or a device such as a smart phone enabling player tracking. FIG. 2 also depicts utilizing a ticket printer 222 to print tickets for a TITO system server 108. Gaming device 200 may further include a bill validator 234, player-input buttons 236 for player input, cabinet security sensors 238 to detect unauthorized opening of the cabinet 218, a primary game display 240, and a secondary game display 242, each coupled to and operable under the control of game controller 202.

The games available for play on the gaming device 200 are controlled by a game controller 202 that includes one or more processors 204. Processor 204 represents a general-purpose processor, a specialized processor intended to perform certain functional tasks, or a combination thereof. As an example, processor 204 can be a central processing unit (CPU) that has one or more multi-core processing units and memory mediums (e.g., cache memory) that function as buffers and/or temporary storage for data. Alternatively, processor 204 can be a specialized processor, such as an application specific integrated circuit (ASIC), graphics processing unit (GPU), field-programmable gate array (FPGA), digital signal processor (DSP), or another type of hardware accelerator. In another example, processor 204 is a system on chip (SoC) that combines and integrates one or more general-purpose processors and/or one or more specialized processors. Although FIG. 2A illustrates that game controller 202 includes a single processor 204, game controller 202 is not limited to this representation and instead can include multiple processors 204 (e.g., two or more processors).

FIG. 2A illustrates that processor 204 is operatively coupled to memory 208. Memory 208 is defined herein as including volatile and nonvolatile memory and other types of non-transitory data storage components. Volatile memory is memory that do not retain data values upon loss of power. Nonvolatile memory is memory that do retain data upon a loss of power. Examples of memory 208 include random access memory (RAM), read-only memory (ROM), hard disk drives, solid-state drives, universal serial bus (USB) flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, examples of RAM include static random access memory (SRAM), dynamic random access memory (DRAM), magnetic random access memory (MRAM), and other such devices. Examples of ROM include a programmable read-only memory (PROM), an erasable programmable read-only memory (EPROM), an electrically erasable programmable read-only memory (EEPROM), or other like memory device. Even though FIG. 2A illustrates that game controller 202 includes a single memory 208, game controller 202 could include multiple memories 208 for storing program instructions and/or data.

Memory 208 can store one or more game programs 206 that provide program instructions and/or data for carrying out various implementations (e.g., game mechanics) described herein. Stated another way, game program 206 represents an executable program stored in any portion or component of memory 208. In one or more implementations, game program 206 is embodied in the form of source code that includes human-readable statements written in a programming language or machine code that contains numerical instructions recognizable by a suitable execution system, such as a processor 204 in a game controller or other system. Examples of executable programs include: (1) a compiled program that can be translated into machine code in a format that can be loaded into a random access portion of memory 208 and run by processor 204; (2) source code that may be expressed in proper format such as object code that is capable of being loaded into a random access portion of memory 208 and executed by processor 204; and (3) source code that may be interpreted by another executable program to generate instructions in a random access portion of memory 208 to be executed by processor 204.

Alternatively, game programs 206 can be set up to generate one or more game instances based on instructions and/or data that gaming device 200 exchanges with one or more remote gaming devices, such as a central determination gaming system server 106 (not shown in FIG. 2A but shown in FIG. 1). For purpose of this disclosure, the term “game instance” refers to a play or a round of a game that gaming device 200 presents (e.g., via a user interface (UI)) to a player. The game instance is communicated to gaming device 200 via the network 214 and then displayed on gaming device 200. For example, gaming device 200 may execute game program 206 as video streaming software that allows the game to be displayed on gaming device 200. When a game is stored on gaming device 200, it may be loaded from memory 208 (e.g., from a read only memory (ROM)) or from the central determination gaming system server 106 to memory 208.

Gaming devices, such as gaming device 200, are highly regulated to ensure fairness and, in many cases, gaming device 200 is operable to award monetary awards (e.g., typically dispensed in the form of a redeemable voucher). Therefore, to satisfy security and regulatory requirements in a gaming environment, hardware and software architectures are implemented in gaming devices 200 that differ significantly from those of general-purpose computers. Adapting general purpose computers to function as gaming devices 200 is not simple or straightforward because of: (1) the regulatory requirements for gaming devices 200, (2) the harsh environment in which gaming devices 200 operate, (3) security requirements, (4) fault tolerance requirements, and (5) the requirement for additional special purpose componentry enabling functionality of an EGM. These differences require substantial engineering effort with respect to game design implementation, game mechanics, hardware components, and software.

One regulatory requirement for games running on gaming device 200 generally involves complying with a certain level of randomness. Typically, gaming jurisdictions mandate that gaming devices 200 satisfy a minimum level of randomness without specifying how a gaming device 200 should achieve this level of randomness. To comply, FIG. 2A illustrates that gaming device 200 could include an RNG 212 that utilizes hardware and/or software to generate RNG outcomes that lack any pattern. The RNG operations are often specialized and non-generic in order to comply with regulatory and gaming requirements. For example, in a slot game, game program 206 can initiate multiple RNG calls to RNG 212 to generate RNG outcomes, where each RNG call and RNG outcome corresponds to an outcome for a reel. In another example, gaming device 200 can be a Class II gaming device where RNG 212 generates RNG outcomes for creating Bingo cards. In one or more implementations, RNG 212 could be one of a set of RNGs operating on gaming device 200. More generally, an output of the RNG 212 can be the basis on which game outcomes are determined by the game controller 202. Game developers could vary the degree of true randomness for each RNG (e.g., pseudorandom) and utilize specific RNGs depending on game requirements. The output of the RNG 212 can include a random number or pseudorandom number (either is generally referred to as a “random number”).

In FIG. 2A, RNG 212 and hardware RNG 244 are shown in dashed lines to illustrate that RNG 212, hardware RNG 244, or both can be included in gaming device 200. In one implementation, instead of including RNG 212, gaming device 200 could include a hardware RNG 244 that generates RNG outcomes. Analogous to RNG 212, hardware RNG 244 performs specialized and non-generic operations in order to comply with regulatory and gaming requirements. For example, because of regulation requirements, hardware RNG 244 could be a random number generator that securely produces random numbers for cryptography use. The gaming device 200 then uses the secure random numbers to generate game outcomes for one or more game features. In another implementation, the gaming device 200 could include both hardware RNG 244 and RNG 212. RNG 212 may utilize the RNG outcomes from hardware RNG 244 as one of many sources of entropy for generating secure random numbers for the game features.

Another regulatory requirement for running games on gaming device 200 includes ensuring a certain level of RTP. Similar to the randomness requirement discussed above, numerous gaming jurisdictions also mandate that gaming device 200 provides a minimum level of RTP (e.g., RTP of at least 75%). A game can use one or more lookup tables (also called weighted tables) as part of a technical solution that satisfies regulatory requirements for randomness and RTP. In particular, a lookup table can integrate game features (e.g., trigger events for special modes or bonus games; newly introduced game elements such as extra reels, new symbols, or new cards; stop positions for dynamic game elements such as spinning reels, spinning wheels, or shifting reels; or card selections from a deck) with random numbers generated by one or more RNGs, so as to achieve a given level of volatility for a target level of RTP. (In general, volatility refers to the frequency or probability of an event such as a special mode, payout, etc. For example, for a target level of RTP, a higher-volatility game may have a lower payout most of the time with an occasional bonus having a very high payout, while a lower-volatility game has a steadier payout with more frequent bonuses of smaller amounts.) Configuring a lookup table can involve engineering decisions with respect to how RNG outcomes are mapped to game outcomes for a given game feature, while still satisfying regulatory requirements for RTP. Configuring a lookup table can also involve engineering decisions about whether different game features are combined in a given entry of the lookup table or split between different entries (for the respective game features), while still satisfying regulatory requirements for RTP and allowing for varying levels of game volatility.

FIG. 2A illustrates that gaming device 200 includes an RNG conversion engine 210 that translates the RNG outcome from RNG 212 to a game outcome presented to a player. To meet a designated RTP, a game developer can set up the RNG conversion engine 210 to utilize one or more lookup tables to translate the RNG outcome to a symbol element, stop position on a reel strip layout, and/or randomly chosen aspect of a game feature. As an example, the lookup tables can regulate a prize payout amount for each RNG outcome and how often the gaming device 200 pays out the prize payout amounts. The RNG conversion engine 210 could utilize one lookup table to map the RNG outcome to a game outcome displayed to a player and a second lookup table as a pay table for determining the prize payout amount for each game outcome. The mapping between the RNG outcome to the game outcome controls the frequency in hitting certain prize payout amounts.

FIG. 2A also depicts that gaming device 200 is connected over network 214 to player tracking system server 110. Player tracking system server 110 may be, for example, an OASIS© system manufactured by Aristocrat© Technologies, Inc. Player tracking system server 110 is used to track play (e.g., amount wagered, games played, time of play and/or other quantitative or qualitative measures) for individual players so that an operator may reward players in a loyalty program. The player may use the player tracking interface 232 to access his/her account information, activate free play, and/or request various information. Player tracking or loyalty programs seek to reward players for their play and help build brand loyalty to the gaming establishment. The rewards typically correspond to the player's level of patronage (e.g., to the player's playing frequency and/or total amount of game plays at a given casino). Player tracking rewards may be complimentary and/or discounted meals, lodging, entertainment and/or additional play. Player tracking information may be combined with other information that is now readily obtainable by a casino management system.

When a player wishes to play the gaming device 200, he/she can insert cash or a ticket voucher through a coin acceptor (not shown) or bill validator 234 to establish a credit balance on the gaming device. The credit balance is used by the player to place wagers on instances of the game and to receive credit awards based on the outcome of winning instances. The credit balance is decreased by the amount of each wager and increased upon a win. The player can add additional credits to the balance at any time. The player may also optionally insert a loyalty club card into the card reader 230. During the game, the player views with one or more UIs, the game outcome on one or more of the primary game display 240 and secondary game display 242. Other game and prize information may also be displayed.

For each game instance, a player may make selections, which may affect play of the game. For example, the player may vary the total amount wagered by selecting the amount bet per line and the number of lines played. In many games, the player is asked to initiate or select options during course of game play (such as spinning a wheel to begin a bonus round or select various items during a feature game). The player may make these selections using the player-input buttons 236, the primary game display 240 which may be a touch screen, or using some other device which enables a player to input information into the gaming device 200.

During certain game events, the gaming device 200 may display visual and auditory effects that can be perceived by the player. These effects add to the excitement of a game, which makes a player more likely to enjoy the playing experience. Auditory effects include various sounds that are projected by the speakers 220. Visual effects include flashing lights, strobing lights or other patterns displayed from lights on the gaming device 200 or from lights behind the information panel 152 (FIG. 1).

When the player is done, he/she cashes out the credit balance (typically by pressing a cash out button to receive a ticket from the ticket printer 222). The ticket may be “cashed-in” for money or inserted into another machine to establish a credit balance for play.

Additionally, or alternatively, gaming devices 104A-104X and 200 can include or be coupled to one or more wireless transmitters, receivers, and/or transceivers (not shown in FIGS. 1 and 2A) that communicate (e.g., Bluetooth® or other near-field communication technology) with one or more mobile devices to perform a variety of wireless operations in a casino environment. Examples of wireless operations in a casino environment include detecting the presence of mobile devices, performing credit, points, comps, or other marketing or hard currency transfers, establishing wagering sessions, and/or providing a personalized casino-based experience using a mobile application. In one implementation, to perform these wireless operations, a wireless transmitter or transceiver initiates a secure wireless connection between a gaming device 104A-104X and 200 and a mobile device. After establishing a secure wireless connection between the gaming device 104A-104X and 200 and the mobile device, the wireless transmitter or transceiver does not send and/or receive application data to and/or from the mobile device. Rather, the mobile device communicates with gaming devices 104A-104X and 200 using another wireless connection (e.g., WiFi® or cellular network). In another implementation, a wireless transceiver establishes a secure connection to directly communicate with the mobile device. The mobile device and gaming device 104A-104X and 200 sends and receives data utilizing the wireless transceiver instead of utilizing an external network. For example, the mobile device would perform digital wallet transactions by directly communicating with the wireless transceiver. In one or more implementations, a wireless transmitter could broadcast data received by one or more mobile devices without establishing a pairing connection with the mobile devices.

Although FIGS. 1 and 2A illustrate specific implementations of a gaming device (e.g., gaming devices 104A-104X and 200), the disclosure is not limited to those implementations shown in FIGS. 1 and 2. For example, not all gaming devices suitable for implementing implementations of the present disclosure necessarily include top wheels, top boxes, information panels, cashless ticket systems, and/or player tracking systems. Further, some suitable gaming devices have only a single game display that includes only a mechanical set of reels and/or a video display, while others are designed for bar counters or tabletops and have displays that face upwards. Gaming devices 104A-104X and 200 may also include other processors that are not separately shown. Using FIG. 2A as an example, gaming device 200 could include display controllers (not shown in FIG. 2A) configured to receive video input signals or instructions to display images on game displays 240 and 242. Alternatively, such display controllers may be integrated into the game controller 202. The use and discussion of FIGS. 1 and 2 are examples to facilitate ease of description and explanation.

FIG. 2B depicts a casino gaming environment according to one example. In this example, the casino 251 includes banks 252 of EGMs 104. In this example, each bank 252 of EGMs 104 includes a corresponding gaming signage system 254 (also shown in FIG. 2A). According to this implementation, the casino 251 also includes mobile gaming devices 256, which are also configured to present wagering games in this example. The mobile gaming devices 256 may, for example, include tablet devices, cellular phones, smart phones and/or other handheld devices. In this example, the mobile gaming devices 256 are configured for communication with one or more other devices in the casino 251, including but not limited to one or more of the server computers 102, via wireless access points 258.

According to some examples, the mobile gaming devices 256 may be configured for stand-alone determination of game outcomes. However, in some alternative implementations the mobile gaming devices 256 may be configured to receive game outcomes from another device, such as the central determination gaming system server 106, one of the EGMs 104, etc.

Some mobile gaming devices 256 may be configured to accept monetary credits from a credit or debit card, via a wireless interface (e.g., via a wireless payment app), via tickets, via a patron casino account, etc. However, some mobile gaming devices 256 may not be configured to accept monetary credits via a credit or debit card. Some mobile gaming devices 256 may include a ticket reader and/or a ticket printer whereas some mobile gaming devices 256 may not, depending on the particular implementation.

In some implementations, the casino 251 may include one or more kiosks 260 that are configured to facilitate monetary transactions involving the mobile gaming devices 256, which may include cash out and/or cash in transactions. The kiosks 260 may be configured for wired and/or wireless communication with the mobile gaming devices 256. The kiosks 260 may be configured to accept monetary credits from casino patrons 262 and/or to dispense monetary credits to casino patrons 262 via cash, a credit or debit card, via a wireless interface (e.g., via a wireless payment app), via tickets, etc. According to some examples, the kiosks 260 may be configured to accept monetary credits from a casino patron and to provide a corresponding amount of monetary credits to a mobile gaming device 256 for wagering purposes, e.g., via a wireless link such as a near-field communications link. In some such examples, when a casino patron 262 is ready to cash out, the casino patron 262 may select a cash out option provided by a mobile gaming device 256, which may include a real button or a virtual button (e.g., a button provided via a graphical user interface) in some instances. In some such examples, the mobile gaming device 256 may send a “cash out” signal to a kiosk 260 via a wireless link in response to receiving a “cash out” indication from a casino patron. The kiosk 260 may provide monetary credits to the casino patron 262 corresponding to the “cash out” signal, which may be in the form of cash, a credit ticket, a credit transmitted to a financial account corresponding to the casino patron, etc.

In some implementations, a cash-in process and/or a cash-out process may be facilitated by the TITO system server 108. For example, the TITO system server 108 may control, or at least authorize, ticket-in and ticket-out transactions that involve a mobile gaming device 256 and/or a kiosk 260.

Some mobile gaming devices 256 may be configured for receiving and/or transmitting player loyalty information. For example, some mobile gaming devices 256 may be configured for wireless communication with the player tracking system server 110. Some mobile gaming devices 256 may be configured for receiving and/or transmitting player loyalty information via wireless communication with a patron's player loyalty card, a patron's smartphone, etc.

According to some implementations, a mobile gaming device 256 may be configured to provide safeguards that prevent the mobile gaming device 256 from being used by an unauthorized person. For example, some mobile gaming devices 256 may include one or more biometric sensors and may be configured to receive input via the biometric sensor(s) to verify the identity of an authorized patron. Some mobile gaming devices 256 may be configured to function only within a predetermined or configurable area, such as a casino gaming area.

FIG. 2C is a diagram that shows examples of components of a system for providing online gaming according to some aspects of the present disclosure. As with other figures presented in this disclosure, the numbers, types and arrangements of gaming devices shown in FIG. 2C are merely shown by way of example. In this example, various gaming devices, including but not limited to end user devices (EUDs) 264a, 264b and 264c are capable of communication via one or more networks 417. The networks 417 may, for example, include one or more cellular telephone networks, the Internet, etc. In this example, the EUDs 264a and 264b are mobile devices: according to this example the EUD 264a is a tablet device and the EUD 264b is a smart phone. In this implementation, the EUD 264c is a laptop computer that is located within a residence 266 at the time depicted in FIG. 2C. Accordingly, in this example the hardware of EUDs is not specifically configured for online gaming, although each EUD is configured with software for online gaming. For example, each EUD may be configured with a web browser. Other implementations may include other types of EUD, some of which may be specifically configured for online gaming.

In this example, a gaming data center 276 includes various devices that are configured to provide online wagering games via the networks 417. The gaming data center 276 may, for example, be a remote gaming server (RGS) or similar system in some implementations. The gaming data center 276 is capable of communication with the networks 417 via the gateway 272. In this example, switches 278 and routers 280 are configured to provide network connectivity for devices of the gaming data center 276, including storage devices 282a, servers 284a and one or more workstations 286b. The servers 284a may, for example, be configured to provide access to a library of games for online game play. In some examples, code for executing at least some of the games may initially be stored on one or more of the storage devices 282a. The code may be subsequently loaded onto a server 284a after selection by a player via an EUD and communication of that selection from the EUD via the networks 417. The server 284a onto which code for the selected game has been loaded may provide the game according to selections made by a player and indicated via the player's EUD. In other examples, code for executing at least some of the games may initially be stored on one or more of the servers 284a. Although only one gaming data center 276 is shown in FIG. 2C, some implementations may include multiple gaming data centers 276.

In this example, a financial institution data center 270 is also configured for communication via the networks 417. Here, the financial institution data center 270 includes servers 284b, storage devices 282b, and one or more workstations 286b. According to this example, the financial institution data center 270 is configured to maintain financial accounts, such as checking accounts, savings accounts, loan accounts, etc. In some implementations one or more of the authorized users 274a-274c may maintain at least one financial account with the financial institution that is serviced via the financial institution data center 270.

According to some implementations, the gaming data center 276 may be configured to provide online wagering games in which money may be won or lost. According to some such implementations, one or more of the servers 284a may be configured to monitor player credit balances, which may be expressed in game credits, in currency units, or in any other appropriate manner. In some implementations, the server(s) 284a may be configured to obtain financial credits from and/or provide financial credits to one or more financial institutions, according to a player's “cash in” selections, wagering game results and a player's “cash out” instructions. According to some such implementations, the server(s) 284a may be configured to electronically credit or debit the account of a player that is maintained by a financial institution, e.g., an account that is maintained via the financial institution data center 270. The server(s) 284a may, in some examples, be configured to maintain an audit record of such transactions.

In some alternative implementations, the gaming data center 276 may be configured to provide online wagering games for which credits may not be exchanged for cash or the equivalent. In some such examples, players may purchase game credits for online game play, but may not “cash out” for monetary credit after a gaming session. Moreover, although the financial institution data center 270 and the gaming data center 276 include their own servers and storage devices in this example, in some examples the financial institution data center 270 and/or the gaming data center 276 may use offsite “cloud-based” servers and/or storage devices. In some alternative examples, the financial institution data center 270 and/or the gaming data center 276 may rely entirely on cloud-based servers.

One or more types of devices in the gaming data center 276 (or elsewhere) may be capable of executing middleware, e.g., for data management and/or device communication. Authentication information, player tracking information, etc., including but not limited to information obtained by EUDs 264 and/or other information regarding authorized users of EUDs 264 (including but not limited to the authorized users 274a-274c), may be stored on storage devices 282 and/or servers 284. Other game-related information and/or software, such as information and/or software relating to leaderboards, players currently playing a game, game themes, game-related promotions, game competitions, etc., also may be stored on storage devices 282 and/or servers 284. In some implementations, some such game-related software may be available as “apps” and may be downloadable (e.g., from the gaming data center 276) by authorized users.

In some examples, authorized users and/or entities (such as representatives of gaming regulatory authorities) may obtain gaming-related information via the gaming data center 276. One or more other devices (such EUDs 264 or devices of the gaming data center 276) may act as intermediaries for such data feeds. Such devices may, for example, be capable of applying data filtering algorithms, executing data summary and/or analysis software, etc. In some implementations, data filtering, summary and/or analysis software may be available as “apps” and downloadable by authorized users.

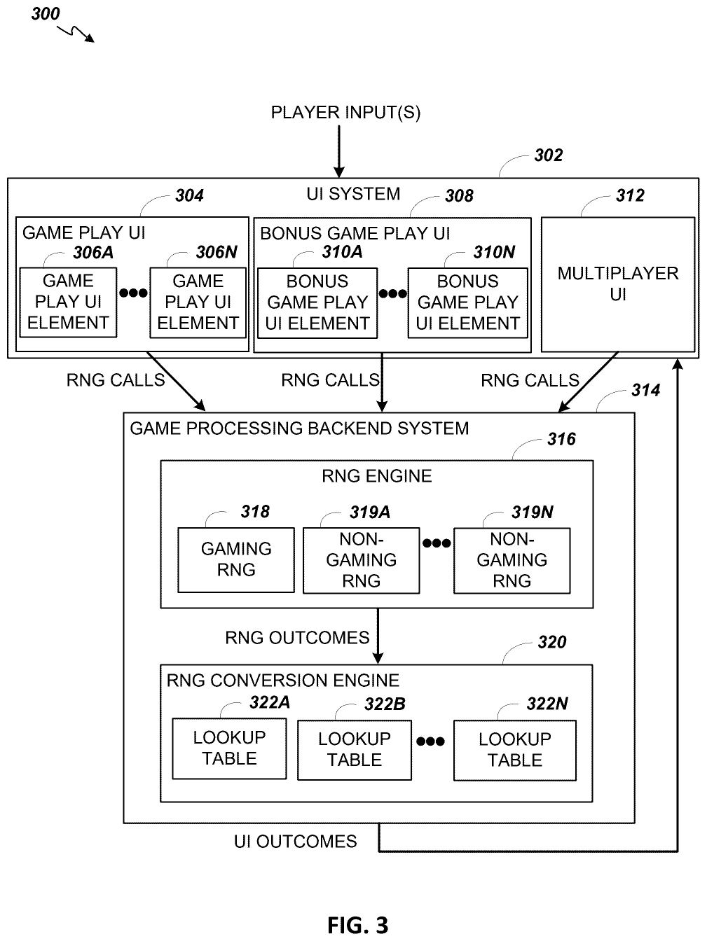

FIG. 3 illustrates, in block diagram form, an implementation of a game processing architecture 300 that implements a game processing pipeline for the play of a game in accordance with various implementations described herein. As shown in FIG. 3, the gaming processing pipeline starts with having a UI system 302 receive one or more player inputs for the game instance. Based on the player input(s), the UI system 302 generates and sends one or more RNG calls to a game processing backend system 314. Game processing backend system 314 then processes the RNG calls with RNG engine 316 to generate one or more RNG outcomes. The RNG outcomes are then sent to the RNG conversion engine 320 to generate one or more game outcomes for the UI system 302 to display to a player. The game processing architecture 300 can implement the game processing pipeline using a gaming device, such as gaming devices 104A-104X and 200 shown in FIGS. 1 and 2, respectively. Alternatively, portions of the gaming processing architecture 300 can implement the game processing pipeline using a gaming device and one or more remote gaming devices, such as central determination gaming system server 106 shown in FIG. 1.

The UI system 302 includes one or more UIs that a player can interact with. The UI system 302 could include one or more game play UIs 304, one or more bonus game play UIs 308, and one or more multiplayer UIs 312, where each UI type includes one or more mechanical UIs and/or graphical UIs (GUIs). In other words, game play UI 304, bonus game play UI 308, and the multiplayer UI 312 may utilize a variety of UI elements, such as mechanical UI elements (e.g., physical “spin” button or mechanical reels) and/or GUI elements (e.g., virtual reels shown on a video display or a virtual button deck) to receive player inputs and/or present game play to a player. Using FIG. 3 as an example, the different UI elements are shown as game play UI elements 306A-306N and bonus game play UI elements 310A-310N.

The game play UI 304 represents a UI that a player typically interfaces with for a base game. During a game instance of a base game, the game play UI elements 306A-306N (e.g., GUI elements depicting one or more virtual reels) are shown and/or made available to a user. In a subsequent game instance, the UI system 302 could transition out of the base game to one or more bonus games. The bonus game play UI 308 represents a UI that utilizes bonus game play UI elements 310A-310N for a player to interact with and/or view during a bonus game. In one or more implementations, at least some of the game play UI element 306A-306N are similar to the bonus game play UI elements 310A-310N. In other implementations, the game play UI element 306A-306N can differ from the bonus game play UI elements 310A-310N.

FIG. 3 also illustrates that UI system 302 could include a multiplayer UI 312 purposed for game play that differs or is separate from the typical base game. For example, multiplayer UI 312 could be set up to receive player inputs and/or presents game play information relating to a tournament mode. When a gaming device transitions from a primary game mode that presents the base game to a tournament mode, a single gaming device is linked and synchronized to other gaming devices to generate a tournament outcome. For example, multiple RNG engines 316 corresponding to each gaming device could be collectively linked to determine a tournament outcome. To enhance a player's gaming experience, tournament mode can modify and synchronize sound, music, reel spin speed, and/or other operations of the gaming devices according to the tournament game play. After tournament game play ends, operators can switch back the gaming device from tournament mode to a primary game mode to present the base game. Although FIG. 3 does not explicitly depict that multiplayer UI 312 includes UI elements, multiplayer UI 312 could also include one or more multiplayer UI elements.

Based on the player inputs, the UI system 302 could generate RNG calls to a game processing backend system 314. As an example, the UI system 302 could use one or more application programming interfaces (APIs) to generate the RNG calls. To process the RNG calls, the RNG engine 316 could utilize gaming RNG 318 and/or non-gaming RNGs 319A-319N. Gaming RNG 318 could corresponds to RNG 212 or hardware RNG 244 shown in FIG. 2A. As previously discussed with reference to FIG. 2A, gaming RNG 318 often performs specialized and non-generic operations that comply with regulatory and/or game requirements. For example, because of regulation requirements, gaming RNG 318 could correspond to RNG 212 by being a cryptographic RNG or pseudorandom number generator (PRNG) (e.g., Fortuna PRNG) that securely produces random numbers for one or more game features. To securely generate random numbers, gaming RNG 318 could collect random data from various sources of entropy, such as from an operating system (OS) and/or a hardware RNG (e.g., hardware RNG 244 shown in FIG. 2A). Alternatively, non-gaming RNGs 319A-319N may not be cryptographically secure and/or be computationally less expensive. Non-gaming RNGs 319A-319N can, thus, be used to generate outcomes for non-gaming purposes. As an example, non-gaming RNGs 319A-319N can generate random numbers for generating random messages that appear on the gaming device.

The RNG conversion engine 320 processes each RNG outcome from RNG engine 316 and converts the RNG outcome to a UI outcome that is feedback to the UI system 302. With reference to FIG. 2A, RNG conversion engine 320 corresponds to RNG conversion engine 210 used for game play. As previously described, RNG conversion engine 320 translates the RNG outcome from the RNG 212 to a game outcome presented to a player. RNG conversion engine 320 utilizes one or more lookup tables 322A-322N to regulate a prize payout amount for each RNG outcome and how often the gaming device pays out the derived prize payout amounts. In one example, the RNG conversion engine 320 could utilize one lookup table to map the RNG outcome to a game outcome displayed to a player and a second lookup table as a pay table for determining the prize payout amount for each game outcome. In this example, the mapping between the RNG outcome and the game outcome controls the frequency in hitting certain prize payout amounts. Different lookup tables could be utilized depending on the different game modes, for example, a base game versus a bonus game.

After generating the UI outcome, the game processing backend system 314 sends the UI outcome to the UI system 302. Examples of UI outcomes are symbols to display on a video reel or reel stops for a mechanical reel. In one example, if the UI outcome is for a base game, the UI system 302 updates one or more game play UI elements 306A-306N, such as symbols, for the game play UI 304. In another example, if the UI outcome is for a bonus game, the UI system could update one or more bonus game play UI elements 310A-310N (e.g., symbols) for the bonus game play UI 308. In response to updating the appropriate UI, the player may subsequently provide additional player inputs to initiate a subsequent game instance that progresses through the game processing pipeline.

Electronic gaming machines (EGMs) such as those discussed above may have cabinets with access panels, doors, slide-out trays, or separate enclosures (e.g., a bill validator cage) within the cabinet. The cabinet houses numerous components, such as electronic components that include printed circuit boards (PCBs), batteries, and memory cards. Some EGMs may position the electronic components at or near a side wall of a cabinet having one or more openings which can provide for airflow around the electronics and/or heat dissipation away from the electronics and potentially out of the cabinet. Some EGMs may have fans that blow air into and/or out of the internal cabinet to cool the internal cabinet, including electrical components inside the cabinet.

However, some EGMs have been designed to position electronics, such as a PCB or an electronics assembly having a mounting tray with the PCB and optionally one or more batteries and/or one or more memory cards, within the internal compartment of the cabinet without a direct access to the environment outside of the cabinet. For example, some new EGMs position these electronics inside the internal compartment such that the electronics are away from an opening or fan in the EGM, there are no fans in the cabinet, or there are limited openings or vents on the cabinet. While this new placement may be advantageous for various purposes, it may have unwanted effects, such as reduced airflow to the electronics assembly and its components, which can lead to accumulation of dust and other unwanted contaminants onto the PCB, batteries, and/or memory cards thereon. This accumulation of material can be detrimental to the functionality of the PCB, batteries, and graphics card. Another unwanted effect of this new placement is reduced heat dissipation from the electronics assembly and its components. Provided herein are new and novel dust covers for an electronics assembly having a mounting tray, a PCB mounted thereon, and in some implementations, one or more batteries and/or one or more memory cards.

The dust cover is configured to reduce accumulation of dust, moisture, smoke, and other contaminants on electronic components inside the EGM cabinet, such as the PCB, a graphics card (which may be a type of PCB), one or more batteries, one or more memory cards, or a combination thereof. In some implementations, an electronics assembly of an EGM has one or more batteries, one or more PCBs, and optionally the one or more memory cards, positioned on a mounting structure (or mounting tray) that can be positioned inside and/or removed from the EGM.

The dust cover is configured to be positioned on the mounting tray and over at least a portion of the PCB, e.g., at least 50%, 75%, or 85% of the PCB. This may include positioning the dust cover such that the PCB is interposed between a portion of the mounting tray and the dust cover. The dust cover may have a planar body portion that may be positioned parallel, or substantially parallel, to the PCB. The dust cover may also have a plurality of side walls that partially define one or more compartments, such as a compartment over the PCB, another compartment around the one or more batteries, and yet another compartment around the one or more memory cards. The side walls may extend from the planar body portion and be arranged perpendicular to, or substantially perpendicular to, the planar top surface of the planar body portion. For each compartment, the side walls may not extend fully around each compartment and/or the side walls may have variable heights. The dust cover may also have removable covers over respective compartments, and the removable covers are advantageously configured to be removed without a tool, such as without a screwdriver. The dust cover also has a curved airflow surface that is advantageously configured to direct air flow towards a heat sink thermally connected to the PCB of the electronics assembly. For example, the planar body portion of the dust cover may define an opening adjacent or near the curved airflow surface, the heat sink may extend through the opening, and the curved airflow surface may direct airflow in various directions, such as downwards away from the heat sink to assist with heat dissipation of the PCB, and downwards towards a second heat sink which may assist with heat dissipation of the second heat sink. In some embodiments, the curved airflow surface may direct airflow upwards towards the heat sink.

FIG. 4 depicts an off-angle view of a dust cover in accordance with disclosed embodiments. The dust cover 400 has a planar body portion 402 having a planar top surface 404, the outer boundary of which is identified with a dash-dot-dash line, and a thickness T in a direction perpendicular to the planar top surface 404. Although the planar body portion 402 may have some non-planar features, the planar body portion 402 may be considered to have an average nominal planarity or flatness. The dust cover 400 also has a plurality of side walls 406 extending from the planar body portion 402 in a direction perpendicular to, or substantially perpendicular to (e.g., within 5%, 10%, or 15% of perpendicular), the planar top surface 404. Three side walls are labeled 406A-C in FIG. 4. As discussed in more detail below, the side walls define a plurality of compartments of the dust cover 400.

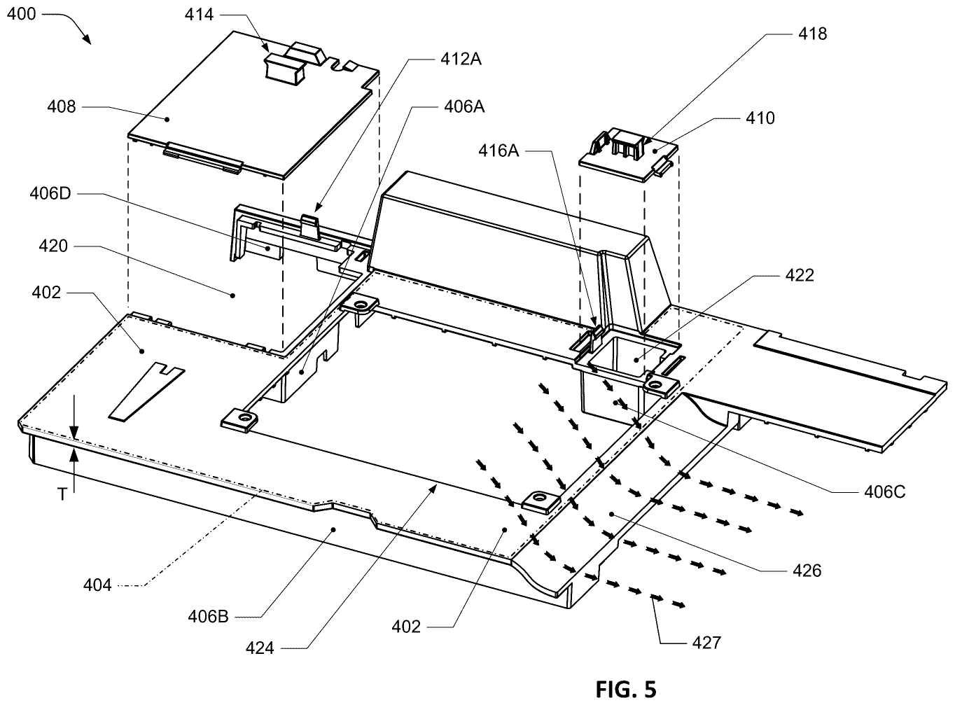

In some implementations, the dust cover 400 has one or more removable covers 408 and 410 that are connected to the planar body portion 402 and configured to be removed without the use of a tool. These removable covers 408 and 410 advantageously allow access to components underneath the dust cover without moving or removing the dust cover. This can prevent exposing all of the electronic components underneath the dust cover to dust, moisture, smoke, and other contaminants, as well as preventing damage to the dust cover and/or the PCB during removal and reinstallation of the dust cover. Further, the ability for the removable covers to be connected to and disconnected from the planar body portion 402 without the use of tools advantageously makes maintenance, access, and repairs easier, faster, and reduces the opportunities for securement components, like screws, to be lost or dropped into the EGM or PCB. In some embodiments, like shown in FIGS. 4 and 5, the first removable cover 408 is a different size, e.g., bigger in this example, than the second removable cover 410.

In some embodiments, the connection means for connecting each removable cover 408 and 410 to the planar body portion may differ. These connection means may include snap joints like a cantilever snap joint, an L-shaped snap joint, an annular snap joint, a U-shaped snap joint, a trap, a wedge-in-slot, a cantilever hook, or a torsional snap joint. These such connection means do not require a tool, such as a screwdriver, to be operated. In some instances, the movable part of a snap joint may be positioned on the planar body portion 402 while in other implementations, the movable part of a snap joint may be positioned on the removable cover. In some instances, each removable cover may have a gripping structure that provides a structure that can be grabbed, held, or secured by a person, such as by the person's fingers.

In FIG. 4, the first removable cover 408 is connected to the planar body portion 402 with a first connection means 412 and has a first gripping structure 414. The second removable cover 410 is connected to the planar body portion 402 with a second connection means 416 and has a second gripping structure 418. The first and connection means 412 and 416 are each illustrated as a snap joint with a cantilever snap joint positioned on the planar body portion 402. Each cantilever snap joint engages with a surface on the respective removable cover. The configuration of the first and second removable covers 408 and 410 may allow a person to grip the gripping structure 414 with one hand while releasing the snap joint with the same or other hand.

FIG. 5 depicts an exploded view of the dust cover of FIG. 4. Here, the first removable cover 408 and the second removable cover 410 have been removed from the planar body portion 402. In this Figure, the cantilever snap joint of each connection means 412 is labeled as 412A and 416A, respectively, and is seen positioned on the planar body portion 402. Also visible in FIG. 5 are two compartments that are covered, respectively, by the first and second removable covers 408 and 410. A first compartment 420 corresponds with the first removable cover 408 such that the first removable cover 408 is configured to be positioned over and cover the first compartment 420. The first compartment 420 is also at least partially defined by one or more side walls, including side walls 406A and 406D. Similarly, a second compartment 422 corresponds with the second removable cover 410 such that the second removable cover 410 is configured to be positioned over and cover the second compartment 422. The second compartment 422 is also at least partially defined by one or more side walls, including side wall 406C. As discussed below, side wall 406C may extend around all of the second compartment 422. As also discussed below, the side walls extending around the first and second compartments 420 and 422 advantageously provide some isolation from contamination between adjacent compartments, e.g., when one of the removable covers is removed.

Returning back to FIG. 4, the planar body portion 402 may also have an opening 424 that extends through and is defined by the planar body portion 402. The opening 424 also extends through the planar top surface 404 and is configured to receive a heat sink such that the heat sink extends through the opening 424, as discussed below. This configuration may advantageously provide for the dust cover to prevent or reduce the accumulation of dust, moisture, smoke and other contaminants on the PCB while concurrently providing the PCB with heat dissipation through the heat sink. The opening 424 may have various shapes, such as rectangular as illustrated, square, circular, oval, elliptical, or obround, for example. Such shapes may match, or substantially match, the shape of the heat sink in order for the dust cover 400 to provide coverage over the PCB around the heat sink.

In some embodiments, the dust cover 400 may also have a curved airflow surface 426 that is connected to the planar body portion 402. The curved airflow surface 426 is configured to direct air flow in one or more directions to assist with heat dissipation from the PCB positioned underneath the dust cover 400. In some embodiments, the curved airflow surface 426 is configured to direct air flow away from the heat sink extending through the opening 424. Example air flow 427 is illustrated with black arrows in FIGS. 4-6 and as can be seen, air contacting the curved airflow surface 426 is caused to flow at a downwards angle. In some other embodiments, the curved airflow surface 426 is configured to direct air flow upwards towards the heat sink. The curved airflow surface 426 is positioned below, or substantially below, the planar top surface 404. The curved airflow surface 426 has a surface proximal end 428 connected to the planar body portion 402 and a surface distal end 430 offset from the planar body portion 402. When viewed from an angle parallel to the planar top surface 404, at least a portion of the curved airflow surface 426, including its surface distal end 430, is below the planar top surface 404.

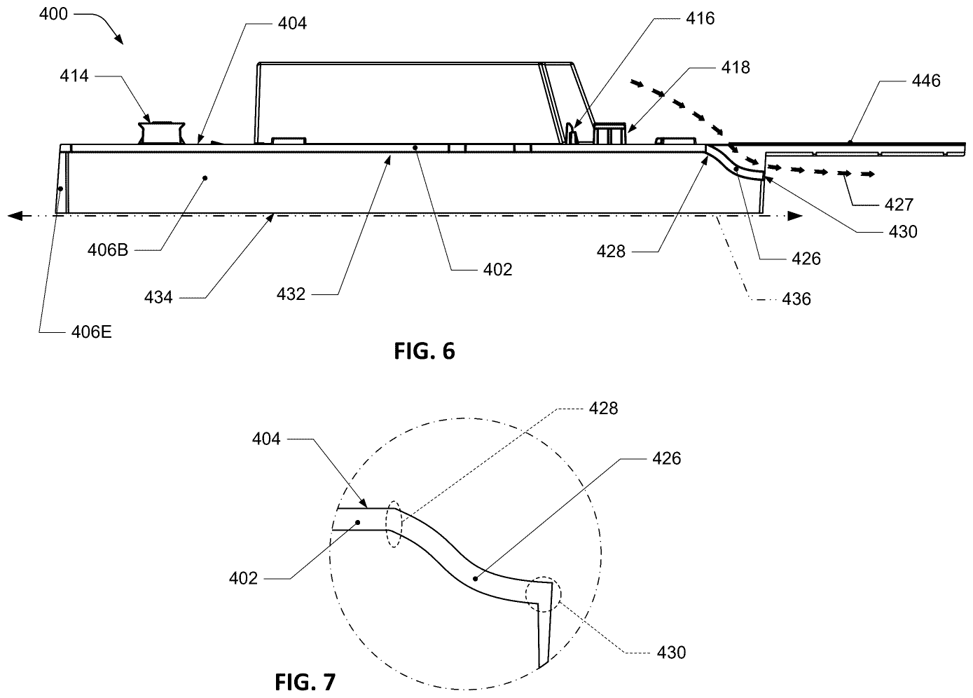

FIG. 6 depicts a front view of the dust cover of FIG. 4. Here, the planar body portion 402 and its planar top surface 404 are visible, and the view in this Figure may be considered parallel to the planar top surface 404. The curved airflow surface 426 is also illustrated along with its surface proximal end 428 connected to the planar body portion 402 and the surface distal end 430 offset from the planar body portion 402 and below the planar top surface 404. FIG. 7 depicts a magnified detail view of a portion of FIG. 6. As illustrated in FIGS. 6 and 7, at least a portion of the curved airflow surface 426, or all of the curved airflow surface 426, is below the planar top surface 404. As also seen in FIGS. 6 and 7, the curved airflow surface 426 has a cross-sectional profile that is nonlinear and has one or more curves, such as an S-shaped cross-sectional profile illustrated here. In some embodiments, the curved airflow surface 426 may have a cross-sectional profile that has a concave section and a convex section, that has a single concave section (e.g., curved up), that has a single convex section (e.g., curved down), that is partially sinusoidal, that is sinusoidal, that is doubly curved, that has two curves. Referring back to FIG. 4, the curved airflow surface 426 extends for a linear width W and the cross-sectional area of the curved airflow surface 426 is swept along the width W.

In FIG. 6, side wall 406B and side wall 406E are also visible. In some embodiments, the side walls including side walls 406A-E extend from the planar body portion 402 in a direction perpendicular to, or substantially perpendicular to (e.g., within 5%, 10%, or 15% of perpendicular), the planar top surface 404. Each side wall, such as side wall 406B, has a proximate end 432 connected to the planar body portion 402 and a distal end 434 offset from the planar body portion 402. The distal ends 434 of the side walls 406 together form a reference plane 436 that may be parallel to the planar top surface 404, in some embodiments, for clarity, this reference plane 436 is shown slightly offset below the distal end 434 of the side wall 406B. As shown, a portion of the curved airflow surface 426 including the surface distal end 430, or all of the curved airflow surface 426, is interposed between the planar top surface 404 and the reference plane 436, and between the planar body portion 402 and the reference plane 436.

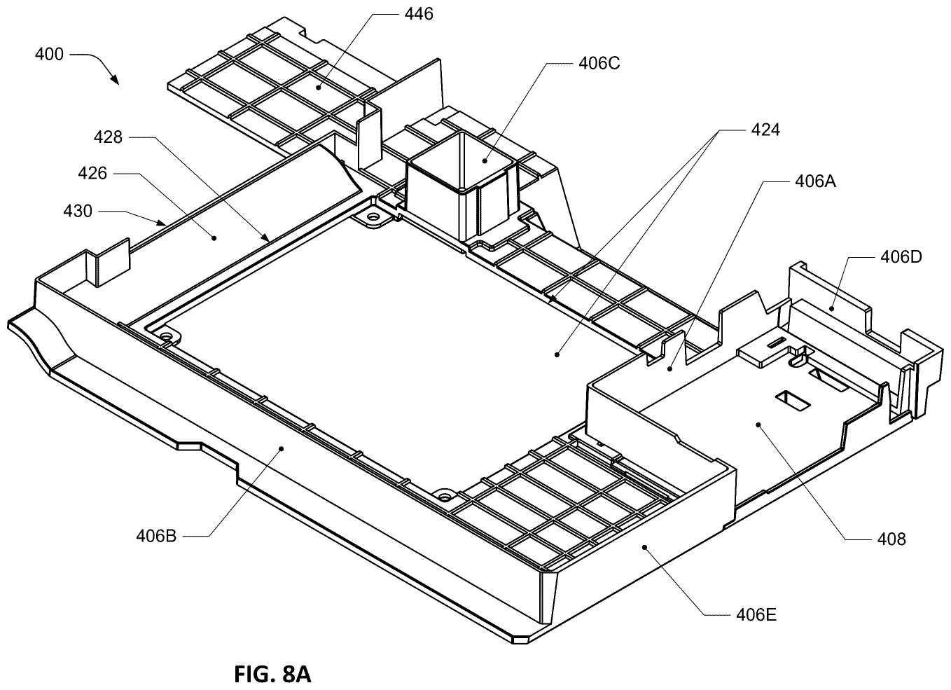

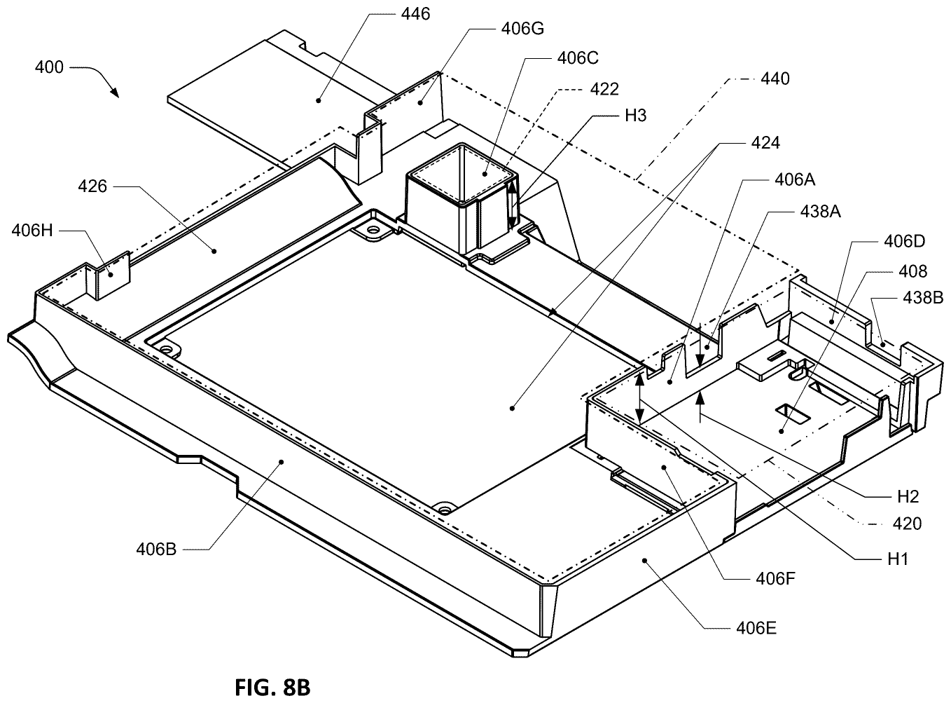

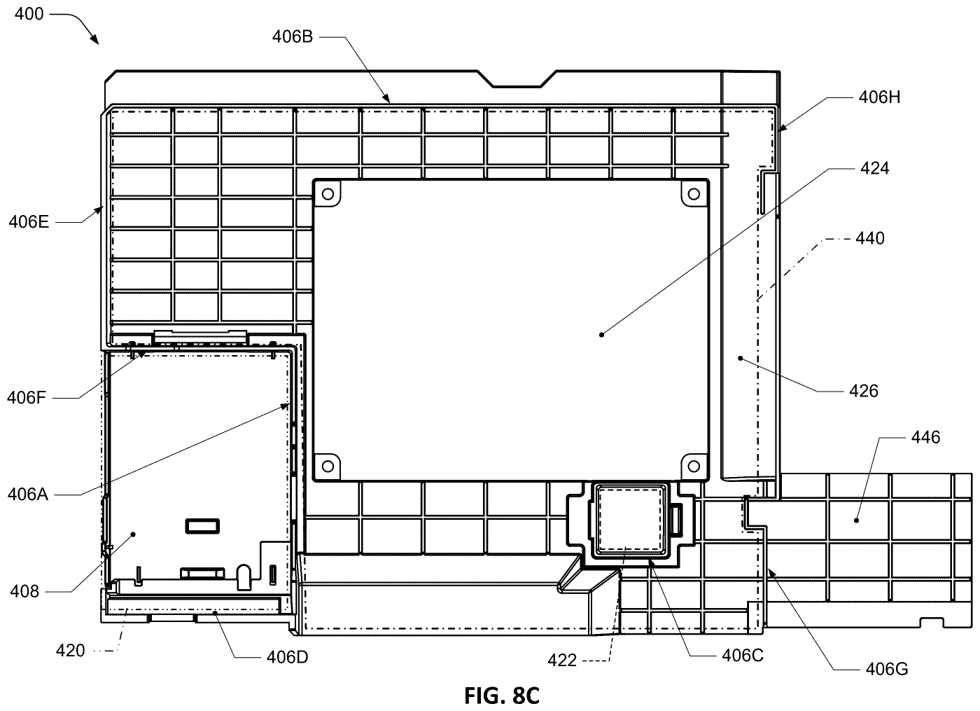

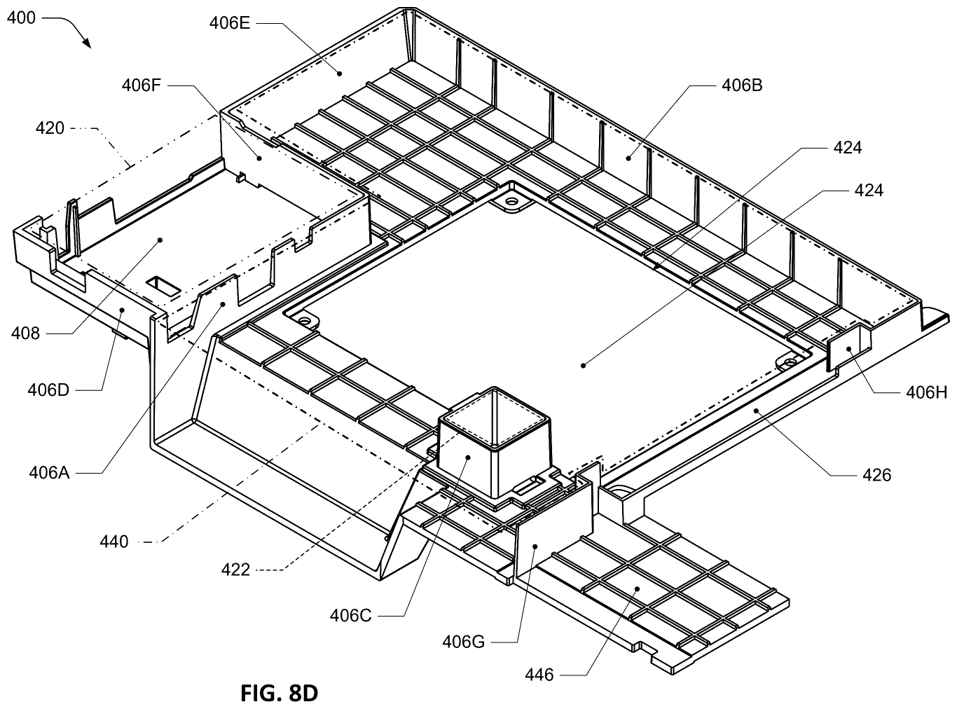

Some of the features of the dust cover 400 are more visible in FIG. 8A which depicts a different off-angle view of the dust cover of FIG. 4. This viewing angle is of the underside, or bottom, of the dust cover 400. Here, the side walls are more visible and are labeled 406A-406E. The opening 424 and curved airflow surface 426 along with curved airflow surface's 426 surface proximal end 428 and surface distal end 430 are also shown. In some implementations, a single side wall may extend around portions of multiple sides of a compartment. For example, in FIG. 8, side wall 406B is the same contiguous structure as side walls 406E and 406A, and these side walls define portions of at least two sides of a single compartment. Side wall 406A also forms some of the first compartment over which the first removable cover 408 is configured to be positioned. In another example, side wall 406C extends around all of the second compartment that corresponds to removable cover 410 (not visible here). This side wall 406C may be one contiguous structure that extends around all of the second compartment. In some embodiments, a side wall may have a variable height, a notch, or a cutout. For instance, side wall 406A has a section with a first height H1 and a second section with a second height H2 smaller than the first height H1 and thereby forming a cutout 438. Similarly, side wall 406D has a variable height forming cutout 438B

Some of the compartments are illustrated in FIG. 8B which depicts the dust cover of FIG. 8A in accordance with various embodiments. Here, some features are removed from the dust cover 400 in FIG. 8A for clarity. For instance, the underside of the planar body portion 402 may have structural supports, such as linear sections 444. In FIG. 8B, these features are removed to illustrate other features. In FIG. 8B, the first compartment 420 is outlined with a dash-dot-dot boundary line and it is formed at least in part by side walls 406A, 406D, and side wall 406F. In some instances, like illustrated in FIGS. 8A and 8B, side walls 406A, 406D, and 406F are a single structure, or a single side wall that follows a nonlinear path. One or more of these side walls, such as side walls 406A and 406F also form another compartment, compartment 440 which is the largest depicted compartment and outlined with a dash-dot-dash boundary. Compartment 440 is formed by side walls 406B, 406E, 406F, 406A, 406G, and 406H. As shown, side walls 406H, 406B, 406E, 406F, and 406A are a single structure. In some other embodiments, one or more of these side walls may be separate from other side walls. The second compartment 422, outlined with a dashed boundary line, is also shown and formed by side wall 406C. This side wall 406C extends around all of the second compartment 422 and may have a constant height H3.

As mentioned above, the side walls provide numerous advantages. For example, some side walls can prevent or reduce dust, smoke, moisture and other contaminant accumulation to the PCB and/or other electronic components when one removable cover is removed temporarily, or for a longer time period (e.g., if it falls off or is inadvertently not put back in place). The side walls isolate or somewhat protect other compartments from dust, smoke, moisture, or other contaminants from entering the other compartments while the removable cover is removed. For example, when the removable cover 408 over the first compartment 422 is removed, the side walls 406A and 406F around the first compartment 420 prevent, or reduce, dust, smoke, moisture and other contaminants that enter the first compartment 420 from entering other compartments, like compartments 440 and 422, adjacent to the first compartment 420. Similarly, when the second removable cover 410 over the second compartment 422 is removed, the side wall 406C around the second compartment 422 prevents, or reduces, dust, smoke, moisture and other contaminants that enter the second compartment 422 from entering other compartments, like compartments 440 and 420.

For further illustration, FIG. 8C depicts a bottom view of the dust cover of FIG. 8A, in accordance to disclosed embodiments, FIG. 8D is yet another off-angle view of the dust cover of FIG. 4, which identifies at least some of features provided herein.

In some embodiments, the dust cover 400 may have additional features for reducing or preventing accumulation of unwanted materials on PCBs or other electronic components. For example, referring back to FIG. 4, the dust cover 400 may have a peninsula 446 that extends from the planar body portion 402. Here, the peninsula 446 is encircled with a dashed shape and it has a first surface 448 that may be coplanar with the planar top surface 404 of the planar body portion 402. This peninsula 446 may provide coverage for other electrical components, such as a graphics card or other portion of the PCB, and prevent or reduce the accumulation of dust, moisture, smoke, or other contaminant on that component. In some embodiments, the peninsula 446 may be configured to extend around a second heat sink.

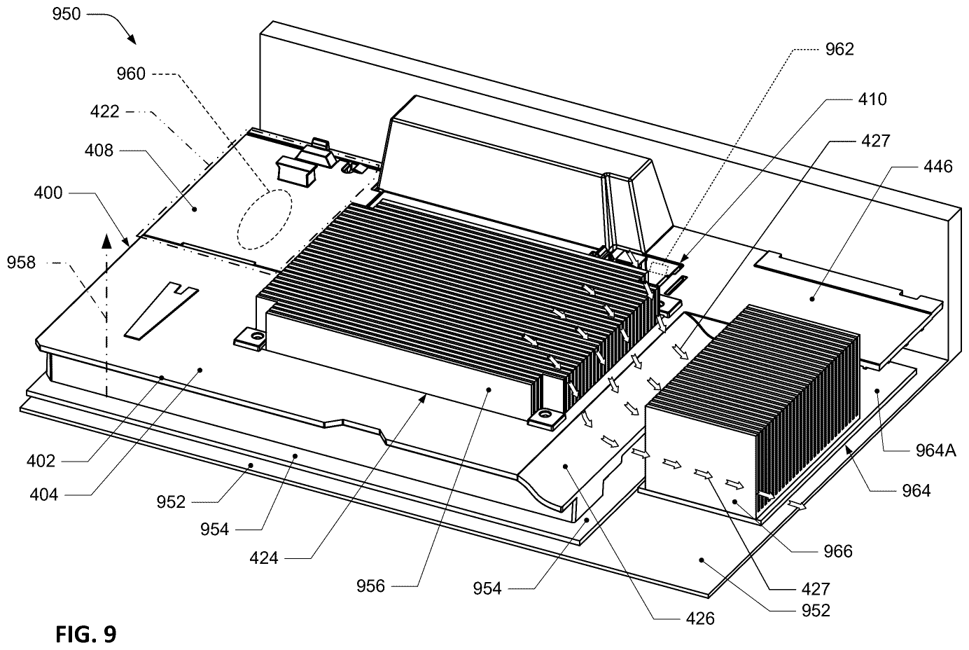

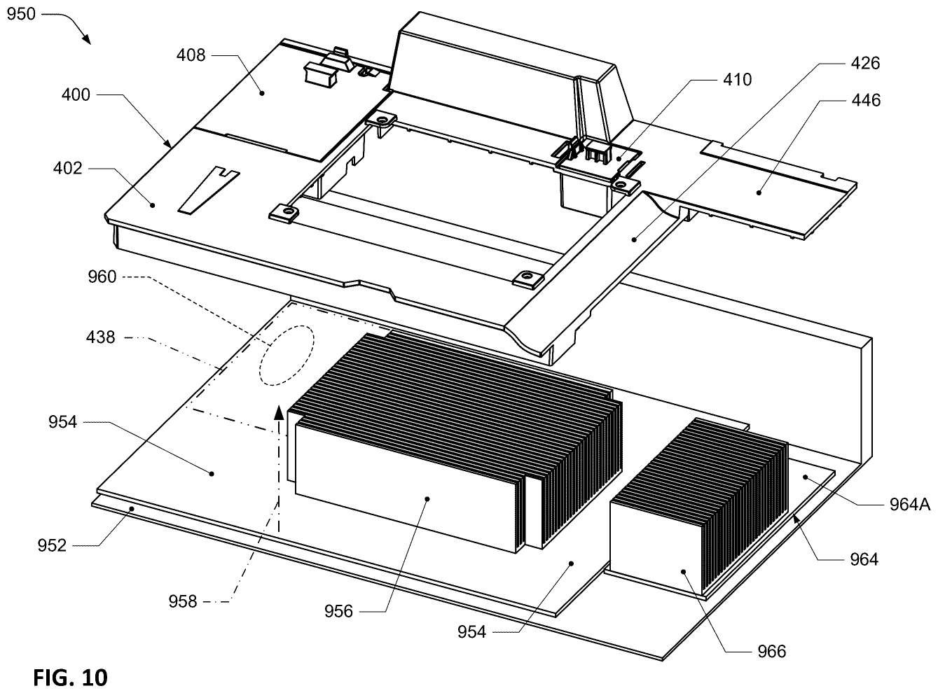

As mentioned above, the dust cover may be a part of an electronics assembly that has at least the PCB. FIG. 9 depicts an off-angle view of an electronics assembly in accordance with disclosed embodiments and FIG. 10 depicts an off-angle exploded view of the electronics assembly of FIG. 9 in accordance with disclosed embodiments. The electronics assembly 950 in these Figures has a mounting tray 952 and a printed circuit board (PCB) 954 that is connected, directly or indirectly, to the mounting tray 952. This connection may include the PCB 954 connected directly to the mounting tray 952 via one or more connectors or the PCB 954 connected directly to an intermediate or other structure, such as a support surface, and this structure may be directly connected to the mounting tray 952. The electronics assembly 950 also has a heat sink 956 that is thermally connected to the PCB 954. In some implementations, the heat sink 956 may be considered a part of the PCB 954. The heat sink 956 extends away from the PCB 954 in a first direction 958 that may be perpendicular to the PCB 954 and/or the mounting tray 952.

The electronics assembly 950 also has the dust cover 400 provided herein. The dust cover 400 is connected, directly or indirectly, to the mounting tray 952. This connection may include the dust cover 400 connected directly to the mounting tray 952 via one or more connectors or the dust cover 400 connected directly to another structure, such as the heat sink 956, and this structure may be directly connected to the mounting tray 952. For example, connection features 435A-435D, e.g., structures having holes, are identified in FIG. 4 and may be used for securing the dust cover 400 to the heat sink 956, such as by using screws or bolts passing through the holes of these connection features 435A-435D into the heat sink 956. The heat sink 956 is also seen extending through the opening 424 of the dust cover 400. This positioning advantageously provides the heat sink 956 the ability to dissipate heat without being covered by the dust cover 400 such that the dust cover 400 does not retain the heat in the heat sink 956. The PCB 954 is also seen interposed between the mounting tray 952 and the planar body portion 402 of the dust cover 400. The dust cover 400 is configured to cover portions of the PCB, excluding the heat sink area, such as at least 50%, 75%, 85%, or 90% of the PCB 954, as illustrated.

As shown in FIG. 9, the curved airflow surface 426 is interposed between the planar top surface 404 of the planar body portion 402 and the PCB 454. The curved airflow surface 426 is further positioned adjacent to the opening 424 and the heat sink 956 which is configured to cause the surface 426 to deflect, or direct, air flow away from the heat sink 956, illustrated with arrows 472, which may assist with heat dissipation from the heat sink 956.

The electronics assembly 950 may also have one or more batteries 960 positioned inside the first compartment 420 and underneath the first removable cover 408. One battery 960 is shown in dashed lines to indicate it is under the first removable cover 408. As provided above, the first removable cover 408 is configured to be removed without the use of a tool, and without removing the dust cover, in order to access the one or more batteries.

The electronics assembly 950 may also have sections for connectivity to one or more memory devices positioned inside the second compartment 422 (not labeled here) and underneath the second removable cover 410. One memory device 962 is shown in dashed lines to indicate it is under the second removable cover 410. As provided above, the second removable cover 410 is configured to be removed without the use of a tool, and without removing the dust cover, in order to access, connect, and disconnect the one or more memory devices. The one or more memory devices may be a memory card like an SSD card, in some implementations.

In some embodiments, the electronics assembly 950 may have a second PCB 964, such as a graphics card, that may have a second heat sink 966 thermally connected thereto. The dust cover 400 is configured to cover some of the second PCB 964 without covering the second heat sink 966. For instance, the peninsula 446 is configured to cover one portion 964A of the second PCB 964 and to not cover the second heat sink 966 so that the second heat sink 966 can dissipate heat. As further illustrated in FIG. 9, the curved airflow surface 426 is interposed between the heat sink 956 and the second heat sink 966. In some instances, like shown, the curved airflow surface 426 extends around one side of the second heat sink 966 and the peninsula 446 extends around another, adjacent side of the second heat sink 966. This positioning of the curved airflow surface 426 is further configured to assist with heat dissipation of both the first and second heat sinks 956 and 966. For example, the curved airflow surface 426 is configured to direct air flow 427 away from the heat sink 956 to the second heat sink 966 and away from the second heat 966 to assist with heat dissipation from both the first and second heat sinks 956 and 966.

The dust cover and electronics assembly described herein may be used for EGMs as well as other machines or devices.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

While the disclosure has been described with respect to the figures, it will be appreciated that many modifications and changes may be made by those skilled in the art without departing from the spirit of the disclosure. Any variation and derivation from the above description and figures are included in the scope of the present disclosure as defined by the claims.

What is claimed is:

1. A dust cover for an electronics assembly, the dust cover comprising:
a planar body portion having a planar top surface;
a plurality of side walls extending from the planar body portion in a direction substantially perpendicular to the planar top surface and at least partially defining a plurality of compartments;
a first removable cover connected to the planar body portion, positioned over a first compartment, and configured to be removable without a tool; and
a curved airflow surface connected to the planar body portion and having a nonlinear cross-sectional profile, wherein:
each side wall has a proximate end connected to the planar body portion and a distal end offset from the planar body portion,
the distal ends of the plurality of side walls form a reference plane that is offset from the planar body portion, and
at least a portion of the curved airflow surface is interposed between the reference plane and the planar body portion.

2. The dust cover of claim 1, wherein the planar body portion defines an opening configured to receive a heat sink.

3. The dust cover of claim 2, wherein the planar body portion extends around all of the opening when viewed perpendicular to the planar top surface.

4. The dust cover of claim 1, wherein the curved airflow surface has a surface proximal end connected to the planar body portion and a surface distal end interposed between the reference plane and the planar body portion when viewed from an angle parallel to the planar top surface.

5. The dust cover of claim 1, wherein:
the curved airflow surface extends for a width in a direction parallel to the planar top surface, and
the curved airflow surface has a nonlinear cross-sectional profile in a direction perpendicular to the width that is curved.

6. The dust cover of claim 5, wherein the nonlinear cross-sectional profile is S-shaped.

7. The dust cover of claim 1, further comprising a peninsula extending from the planar body portion, wherein the peninsula has a first surface co-planar with the planar top surface of the planar body portion.

8. The dust cover of claim 1, further comprising a second removable cover connected to the planar body portion, positioned over a second compartment, and configured to be removable without a tool.

9. The dust cover of claim 8, wherein the first removable cover and the second removable cover are different sizes.

10. The dust cover of claim 1, wherein:
a first subset of side walls extends around all of the first compartment, and
a second subset of side walls extends around at least some of a second compartment.

11. The dust cover of claim 1, wherein two side walls partially define the first compartment and a third compartment.

12. The dust cover of claim 1, wherein the first removable cover is configured to connect with the planar body portion with a snap joint.

13. An electronics assembly, comprising:
a mounting tray;
a printed circuit board (PCB) directly or indirectly connected to the mounting tray;
a heat sink connected to the PCB and extending away from the PCB and the mounting tray in a first direction; and
a dust cover directly or indirectly connected to the mounting tray and having:
a planar body portion having a planar top surface and an opening extending through and defined by the planar body portion, and
a curved airflow surface connected to the planar body portion and having a nonlinear cross-sectional profile,
wherein:
the heat sink extends through the opening,
the PCB is interposed between the mounting tray and the planar body portion of the dust cover, and
at least a portion of the curved airflow surface is interposed between the PCB and the planar body portion.

14. The electronics assembly of claim 13, wherein the curved airflow surface is adjacent to the opening and the heat sink.

15. The electronics assembly of claim 13, wherein the dust cover further has:
a plurality of side walls extending from the planar body portion in a direction substantially perpendicular to the planar top surface and defining a plurality of compartments, and
a first removable cover connected to the planar body portion, positioned over a first compartment, and configured to be removable without a tool.

16. The electronics assembly of claim 15, further comprising one or more batteries, wherein:
the one or more batteries are positioned inside the first compartment, and
the first removable cover is positioned over the one or more batteries.

17. The electronics assembly of claim 15, further comprising one or more memory cards, wherein:
the one or more memory cards are positioned inside the first compartment, and
the first removable cover is positioned over the one or more memory cards.

18. The electronics assembly of claim 17, wherein a first subset of side walls extends around all of the first compartment.

19. The electronics assembly of claim 13, further comprising a second heat sink extending away from the mounting tray in the first direction, wherein the curved airflow surface is interposed between the opening and the second heat sink when viewed perpendicular to the planar top surface.

20. The electronics assembly of claim 19, wherein the dust cover further has a peninsula extending from the planar body portion, wherein:
the peninsula has a first surface co-planar with the planar top surface,
the peninsula is adjacent to the curved airflow surface,
the curved airflow surface extends around a first side of the second heat sink, and
the peninsula extends around a second side of the second heat sink.
